(19) United States
(12) Patent Application Publication
(10) Pub. No.: US 2023/0268192 A1
(43) Pub. Date: Aug. 24, 2023

(54) IN-SITU HYDROCARBON-BASED LAYER FOR NON-CONFORMAL PASSIVATION OF PARTIALLY ETCHED STRUCTURES

(71) Applicant: Lam Research Corporation, Fremont, CA (US)

(72) Inventors: Eric HUDSON, Berkeley, CA (US); Kapu Sirish REDDY, Portland, OR (US); Ragesh PUTHENKOVILAKAM, Portland, OR (US); Shashank DESHMUKH, San Francisco, CA (US); Prabhat KUMAR, Fremont, CA (US); Prabhakara GOPALADASU, Dublin, CA (US); Seokmin YUN, Dublin, CA (US); Xin ZHANG, Fremont, CA (US)

(21) Appl. No.: 18/012,194

(22) PCT Filed: Jun. 13, 2022
(86) PCT No.: PCT/US2022/033292

§ 371 Date: Dec. 21, 2022

Related U.S. Application Data
(60) Provisional application No. 63/210,807, filed on Jun. 15, 2021.

(51) Int. Cl. H01L 21/311; H01L 21/033; H01L 21/02; H01L 21/3213; H01L 21/67

(52) U.S. Cl. CPC H01L 21/31127; H01L 21/0337; H01L 21/02115; H01L 21/32139; H01L 21/02274; H01L 21/67248

(57) ABSTRACT

A method for selectively etching at least one feature in a first region with respect to a second region of a stack is provided. The first region is selectively etched with respect to the second region to form at least one partial feature in the first region, the at least one partial feature having a depth with respect to a surface of the second region. An in-situ a fluorine-free, non-conformal, carbon-containing mask is deposited over the first region and the second region, wherein the carbon-containing mask is selectively deposited on the second region at a second thickness with respect to the first region at a first thickness, the second thickness being greater than the first thickness. The first region is further etched in-situ to etch the at least one partial feature and wherein the carbon-containing mask acts as an etch mask for the second region.

### CROSS-REFERENCE TO RELATED APPLICATION

This application claims the benefit of priority of U.S. Application No. 63/210,807, filed Jun. 15, 2021, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to methods of forming semiconductor devices on a semiconductor wafer. More specifically, the disclosure relates to the selective etching of materials by use of non-conformal passivation.

The smallest feature dimensions of semiconductor devices are constantly shrinking to follow Moore's law. Etching small features within masking layers on a semiconductor wafer can be challenging. One of these features is the contact between the 1^{st} metal layer and the silicon layer with gates and source/drains (S/D).

It is desirable for the hole or trench of the contacts to be very accurately placed in respective to the underlying gate and S/D. Current photolithography tools can only partially meet the placement requirement of the contacts. Therefore, the contact etch can expose the spacer around the gate. Such exposure often leads to corner loss of the space material resulting in an electric leakage.

With respect to etching gate cap layers, tradeoffs between passivation of the cap and reduction of the opening (e.g., contact hole) critical dimension (CD) may cause the final CD to be below target, or an incomplete etch of the contact in regions where the CD is too small or closed.

The current technology relies on passivation via a deposition layer based on fluorocarbon (FC), typically hexafluoro-1,3-butadiene (C₄F₆) and/or hydrofluorocarbon (HFC), typically fluoromethane (CH₃F) precursors, sometimes combined with other reactants. This produces a polymer with moderate density and appreciable fluorine content, which in turn reduces the efficacy of the film at passivating the cap layer. In particular, as higher energy ions impact the passivation film during etch or atomic layer etch (ALE)-activate steps, fluorine in the passivation may become unbound and more likely to react with the cap nitride, promoting cap etch.

### SUMMARY

To achieve the foregoing and in accordance with the purpose of the present disclosure, a method for selectively etching at least one feature in a first region with respect to a second region of a stack is provided. The first region is selectively etched with respect to the second region to form at least one partial feature in the first region, the at least one partial feature having a depth with respect to a surface of the second region. An in-situ a fluorine-free, non-conformal, carbon-containing mask is deposited over the first region and the second region, wherein the carbon-containing mask is selectively deposited on the second region at a second thickness with respect to the first region at a first thickness, the second thickness being greater than the first thickness. The first region is further etched in-situ to etch the at least one partial feature and wherein the carbon-containing mask acts as an etch mask for the second region.

In another manifestation, an apparatus for selectively etching at least one feature in a first region with respect to a second region of a stack is provided. A processor is provided. Non-transitory memory storing instructions are executable by the processor. The instructions, when executed by the processor, perform steps comprising selectively etching the first region with respect to the second region to form at least one partial feature in the first region, the at least one partial feature having a depth with respect to a surface of the second region; depositing in-situ a fluorine-free, non-conformal, carbon-containing mask over the first region and the second region, wherein the carbon-containing mask is selectively deposited on the second region at a second thickness with respect to the first region at a first thickness, the second thickness being greater than the first thickness, and further etching in-situ the first region to etch the at least one partial feature and wherein the carbon-containing mask acts as an etch mask for the second region.

In another manifestation, a method for selectively etching at least one feature in an oxide region with respect to a nitride region of a stack is provided. A stack structure is provided with a nitride region and oxide region in a reactor chamber. CO gas is added in the reactor chamber at a bias of less than 60 W. A carbon-based mask is selectively deposited such that the mask on the nitride region is deposited at a higher rate than on the oxide region, creating a thicker layer on the nitride region than the oxide region. An etch in-situ is performed on the stack, thereby etching the oxide region to form a feature in the oxide region.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow diagram of an embodiment.

FIGS. 2A-D are schematic cross-sectional views of a stack structure processed according to an embodiment.

FIG. 3 is a detailed flow chart of another embodiment.

FIG. 4 schematic cross-sectional view of a structure processed according to another embodiment.

FIG. 5 is a high level flow chart of another embodiment.

FIGS. 6A-D are schematic cross-sectional views of a stack structure processed according to an embodiment

FIG. 7 is a schematic view of a etch chamber that may be used in an embodiment.

FIG. 8 is a schematic view of a computer system that may be used in practicing an embodiment.

### DETAILED DESCRIPTION OF THE EXEMPLARY EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

An aspect of the technology of the present disclosure is a non-conformal, dense carbon layer or film deposited in-situ in the etch tool after partial etch, to enable passivation of a cap layer with a very thin film that minimizes the reduction of the feature (e.g., opening) critical dimension (CD). In one embodiment, deposition of the carbon layer is performed via a Plasma Enhanced Chemical Vapor Deposition (PECVD) process that uses hydrocarbon precursors to generate a fluorine-free carbon layer. Deposition of the carbon layer is not formed by the pre-etch stack deposition but in-situ during the etch process. Thus, the etch and carbon PECVD deposition processes are performed in the same reactor during the same process run.

The processes disclosed herein are particularly useful in etching small features within masking layers on a semiconductor wafer, and in particular the contact between the 1^{st} metal layer and the silicon layer with gates and source/drains (S/D).

Such features are typically prepared by a process called self-aligned contact (SAC). Current SAC etch processes utilize a series of oxide Atomic Layer Etch (ALE) steps to manage tradeoff s between key critical results: (1) minimizing loss of cap material (typically an SiN or lower-k SiON liner) to avoid leakage/short between the contact and gate, and (2) maintaining a large enough CD to produce a robust and complete etch of oxide in the contact to ensure very low contact resistance failure rate (typically <1 in 1e8). In practice, this tradeoff is more complicated because the cap layer has a different surrounding layout of cut mask, leading to a range of shading conditions that all impact the above results. Typically, the more-shaded areas have less passivation and are more prone to excessive cap loss, and the less-shaded areas have more passivation and are more prone to small CD/incomplete etch. This loading effect further limits the process window to avoid the tradeoffs above.

One embodiment of the present technology addresses the current issues by introducing an in-situ PECVD carbon-based passivation film. In such embodiment, a non-conformal carbon PECVD deposition is performed after a partial etch, when the oxide contact has been recessed by at least 20 nm. Subsequent etching of the oxide in the contact occurs with the carbon film providing effective passivation of the cap nitride without introducing issues with small CD and/or incomplete etch. In this case, the initial recess of the oxide creates greater shading at the oxide etch front relative to the cap layer surface. This in turn allows more carbon deposition on the cap layer than at the oxide etch front, which avoids undesired etch stop due to carbon deposition at the etch front.

Another embodiment is a selective deposition process for in-situ passivation of a nitride region with respect to an oxide region, wherein a carbon-based film or mask is selectively deposited on the nitride region at a much higher rate than on the oxide region. In one embodiment, the selective deposition processes may be implemented as part of an etch that is targeted to remove a portion of the oxide region (e.g., comprising SiO₂) for small-CD SAC etching. In this embodiment, the selective deposition process utilizes the distinctive material properties between the two regions, along with the environment within the etch chamber, to generate a selective deposition of a carbon-based mask.

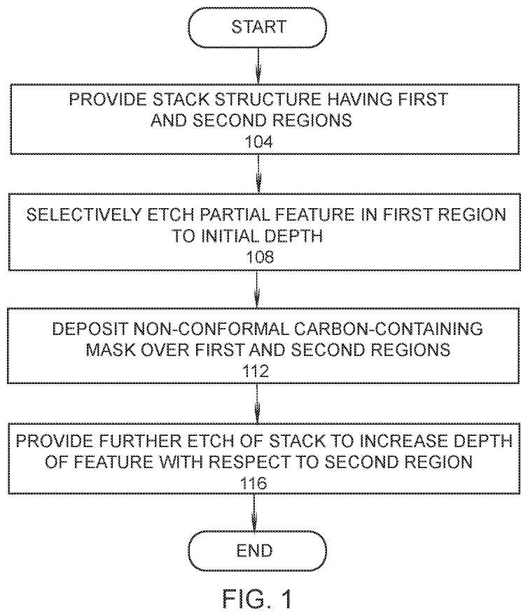

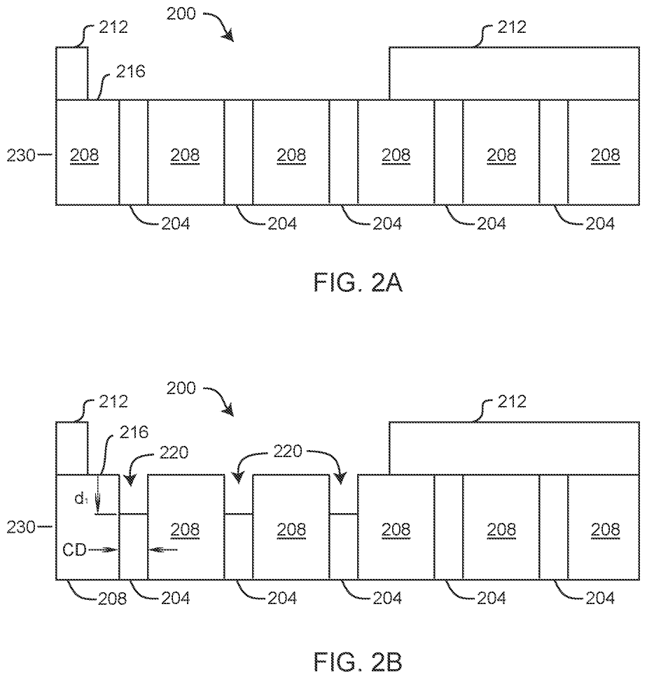

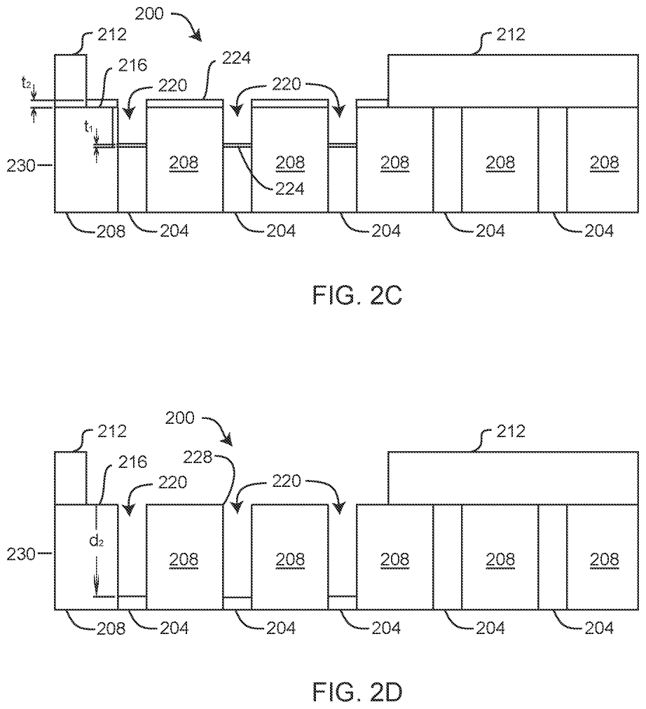

In order to facilitate understanding, FIG. 1 is a high level flow diagram of an embodiment. A stack structure 200 with first and second regions is provided (step 104). FIG. 2A is a schematic cross-sectional view of part of a stack structure 200 with alternating first regions 204 and second regions 208 within layer 230. In one embodiment, layer 230 comprises a layer that eventually forms contacts within first regions 204 and gates within second regions 208. In this example, the first region 204 comprises an oxide region comprising a stable oxide such as silicon oxide, and the second region 208 comprises a lower oxygen region. In one embodiment, the lower oxygen region may further include a lower oxygen silicon containing region having, for example, SiN, silicon oxynitride (SiON), silicon oxycarbonitride (SiOCN), silicon oxynitride (SiON), silicon oxycarbide (SiOC), silicon carbonitride (SiCN), organosilicon oxide (SiOCHx) (back end of line (BEOL) low-k), silicon carbide (SiC) or the like material. In other embodiments, other lower oxygen regions may be used in place of the lower oxygen silicon containing regions. For example, silicon germanium (SiGe), germanium (Ge), elemental metal or metal nitrides may form the lower oxygen regions and may be protected, so that SiO₂ may be selectively etched with respect to these materials. A lower oxygen region has a lower concentration of oxygen than silicon oxide.

It is appreciated that the geometry of the embodiment shown in FIG. 2A through 2D is presented in a simplified form, and specific detail with respect to the elements disclosed therein (e.g., gate or contact structures/geometry) has been omitted for clarity. For example, in various embodiments, the second regions 208 are not composed of a homogenous material, but rather formed from a number of materials or regions that are encased by a cap layer (not shown) comprising a lower oxygen-containing material (e.g. nitride) forming the surface 216 of layer 230, and as well as a nitride spacer (not shown) at the sides of the second regions 208 to form a buffer between first regions 204 and second regions 208.

A mask 212 is formed over surface 216 of the layer 230. In one embodiment, the mask 212 comprises a photolithographic mask of patterned photoresist. As shown in FIG. 2A through FIG. 2D, the mask 212 may be configured to widely expose a number of alternating first regions 204 and second regions 208.

After the stack structure 200 is provided, a selective, partial etch is performed (step 108) that partially etches a feature in one or more of the first regions 204 that are not covered by the photolithographic mask 212. The second region(s) 208 is etched much less than the first region(s) 204. FIG. 2B is a cross-sectional view of the stack structure 200 after the selective partial-etch (step 108) is complete. In this example, the first region(s) 204 not covered by the photolithographic mask 212 are partially etched to form a partial feature 220, in particular a trench or recess, down to a first depth d₁ below the surface of the layer 230. In one embodiment, the depth d₁ is at least 20 nm.

In this embodiment, the feature 220 (e.g., trench or hole) has a critical dimension (CD) or width of less than 10 nm. In various embodiments, the feature 220 has width of between 6 to nm. Thus, the depth-to-width aspect ratio of the feature 220 after the partial etch (step 108) will generally be at least 2:1. In various embodiments, the ultimate depth-to-width aspect ratio of the feature 220 that is etched in the first region 204 is at least 6:1. For example, the feature 220 has a depth to width aspect ratio is between 6:1 and 12:1 or more.

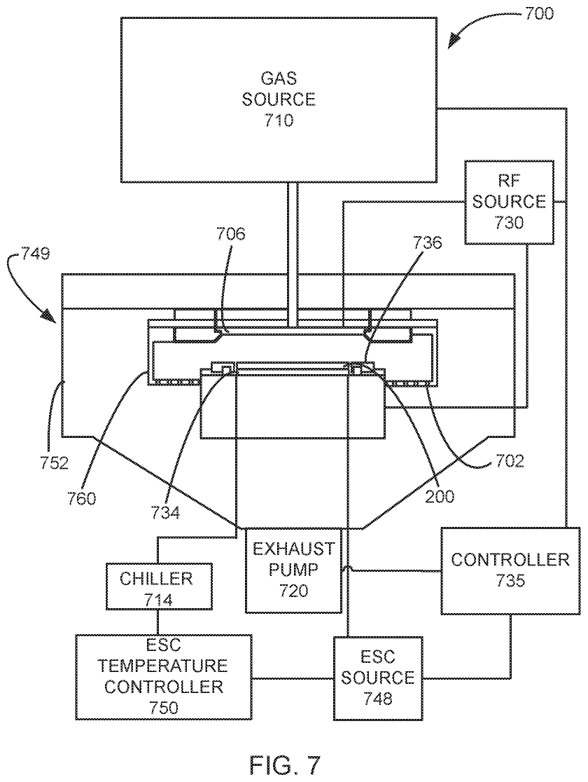

In one embodiment, each first region 204 is selectively etched using an atomic layer etch (ALE) process in a semiconductor processing chamber, and in particular a dielectric etch chamber such as etch chamber 700 provided in FIG. 7. In this embodiment, the ALE provides a reactant gas of hexafluoro-1,3-butadiene (C₄F₆). The C₄F₆ forms a polymer deposition layer over the first (e.g., silicon oxide) region 204 (and the native silicon oxide layer, if any). The reactant gas is purged, and an activation gas of argon (Ar) is provided. The Ar activates the deposition layer causing deposited fluorine to selectively etch the (partial) feature 220 in first region 204.

If desired, the ALE process of selective deposition and selective etch steps may be repeated for a plurality of cycles until the first depth d₁ is achieved. However, because the selectivity of step 104 is not high, some of the second region 208 may also be etched away. Therefore, this etch is only used as a partial etch to establish the desired geometry (e.g., aspect ratio of feature 220) that is preferred for the next step in the process.

In an example, a chamber pressure of 5-500 mTorr is provided. The etch gas comprises 1-200 standard cubic centimeters per minute (sccm) tungsten hexafluoride (WF₆), 1-300 sccm difluoromethane (CH₂F₂), oxygen 1-200 sccm, and 50-1000 sccm Ar. To form the etch, gas and 20-1000 W transformer coupled plasma (TCP) bias is provided. In another embodiment, the etch gas may comprise C₄F₆.

In some embodiments, the etch gas further comprises an oxygen containing component. In some embodiments, the oxygen containing component comprises at least one of oxygen (O₂), ozone (O₃), carbon dioxide (CO₂), carbon monoxide (CO), nitric oxide (NO), nitrogen dioxide (NO₂), nitrous oxide (N₂O), sulfur dioxide (SO₂), sulfur trioxide (SO₃), water (H₂O), peroxide (H₂O₂), and carbonyl sulfide (COS). In various embodiments, the etch gas further comprises an inert gas. In some embodiments, the inert gas is selected from the group consisting of nitrogen, helium, argon, and neon. In various embodiments, a plasma is formed at a pressure of 5-500 millitorr with a power of 30-500 Watts.

After the selective partial-feature etch is completed (step 108), a deposition step (step 112) is performed in-situ in the same chamber used to process the partial etch step 108 to form a fluorine-free, carbon-containing, non-conformal, mask 224 (also referred to as a hard mask) over the non-masked regions of the stack structure 200. As seen in FIG. 2C, the non-conformal mask 224 comprises a layer that is disposed disparately over the first region(s) 204 with respect to the second region(s) 208, and acts as an etch mask for the second region. In particular, the hard mask 224 is selectively deposited on the second region 208 at a second thickness t₂ that is significantly greater than the thickness t₁ that is deposited at etched feature 220 of the recessed first region 204. The non-conformity of the hard mask 224 is primarily a function of geometry, i.e., compared to the level or thickness of deposition at layer surface 216 of layer 230, very little or no deposition occurs within the feature 220 (e.g., trench, recess, or the like) due to greater shading at the etch front (feature 220) relative to the layer surface 216/non-recessed second region 208. In one embodiment, the thickness t₁ at trench or feature 220 ranges from 0 nm to 4 nm. In another embodiment, the thickness t₁ of the mask 224 at feature 220 ranges from 1 nm to 2 nm. Correspondingly, the thickness t₂ of the mask 224 at surface 216/second region 208 ranges from 1 nm to 4 nm.

In an embodiment, the non-conformal mask 224 comprises an in-situ carbon-based passivation film that is applied using a Plasma Enhanced Chemical Vapor Deposition (PECVD) process. Rather than typical fluorine-based precursors (e.g., fluorocarbon (FC, typically C₄F₆) and/or hydrofluorocarbon (HFC, typically CH₃F)), the PECVD process in step 112 utilizes hydrocarbons to generate the non-conformal mask 224, i.e., the gas used in the PECVD process is fluorine-free and halogen-free. Exemplary HC precursors may include C₂H₂ (acetylene), C₂H₄ (ethylene), C₃H₆ (propylene), or the like. The deposited mask 224 comprises a high-density, carbon-based film that is resistant to subsequent etch processes. In some embodiments, the mask 224 comprises a hydrocarbon (HC). In various embodiments, the hydrocarbon-containing layer may be a pure hydrocarbon layer.

In an embodiment, the PECVD non-conformal deposition step 112 is performed under conditions that are compatible with typical etch reactors/chambers. For example, in one embodiment, the non-conformal deposition step 112 is performed such that the mask 224 is deposited at a wafer temperature of between 0° C. and 250° C. In other embodiments, the mask 224 is deposited at a wafer temperature of between 60° C. and 180° C. In a further embodiment, the mask 224 is deposited at a wafer temperature of between 80° C. and 140° C. Additionally, in one embodiment, deposition step 112 is performed such that the mask 224 is deposited with the chamber pressure of 5 mTorr and 500 mTorr. In other embodiments, the mask 224 is deposited with the chamber pressure being less than 200 mTorr.

With deposition step 112 completed, a further etch of the stack structure 200 is performed at etch step 116 in-situ in the same chamber as steps 108 and 112 to add additional depth to the trench or feature 220 with respect to the layer surface 216. As seen in FIG. 2D, the depth of the trench or feature 220 with respect to the layer surface 216 after etch step 116 is increased to depth d₂. In one embodiment, the depth d₂ is the final depth desired for the feature 220, for example a depth desired to reach a fin (not shown) in a fin field-effect transistor (FinFET) composed at least in part of the stack structure 200. In one embodiment, further etch step 116 is performed via an ALE process similar to step 108 detailed above.

Because the mask 224 deposited in step 112 is resistive to the dielectric etch process, the thicker carbon film over the second region 208 provides effective passivation of the second region 208 without introducing issues with respect to the small CD and/or an incomplete etch. In this case, the zero or small thickness of the mask 224 in feature 220 is quickly removed, resulting in selective further etching of the feature 220 while the second region remains substantially etch-free under the cover of the thicker mask 224. Of particular sensitivity to the etch process is the corner 228 of the second region 208. Typically, significant rounding or chamfering of the corner 228 occurs as a result of the contact etching process. However, with the carbon-based, non-conformal mask 224 detailed in FIG. 2C, such rounding is minimized and/or obviated as a result of the proper passivation of second region 208.

The carbon-based, non-conformal mask 224 is superior to the conventional FC or HFC in-situ passivation films due to: (1) higher film density, which increases attenuation of ions per unit thickness and better protects the second region 208 from ion-induced etch reactions and (2) lower to no fluorine content, which removes a potential source of fluorine that has the tendency to promote non-desired etching of the second region 208 inherent in the etch (ALE) process.

In one embodiment, the depth achieved after further etch step 116 is sufficient, i.e., the achieved depth d₂=d_{final}. For example, in one embodiment of a stack structure 200, the depth of the trench or feature 220 is such that when filled with metallic material (in subsequent processing steps not shown) it forms a contact with the appropriate feature in the stack structure 200. In various embodiments, the mask 224 at second region 208 after further etch step 116 is also etched or removed at the point which depth d₂ is reached, without substantially removing any of the second region 208 material. In such embodiment, the thickness t₂ at second region 208 deposited during deposition step 112 may be tuned so that the no or very little material remains after further etch step 116. In other embodiments, an additional post-processing step (e.g., wet clean, ashing or like process) may be used to remove any residual non-conformal mask 224. In one embodiment, an aqueous solution of ammonia (NH₃) and hydrogen peroxide (H₂O₂) is used to selectively remove any remaining non-conformal mask 224. In another embodiment, after etch step 116, an in-situ O₂-based plasma strip is performed in the same reactor to selectively remove any remaining non-conformal mask 224. In another embodiment, after etch step 116, a polymer strip may be performed in a different reactor using typical oxidizing or reducing strip chemistry and conditions.

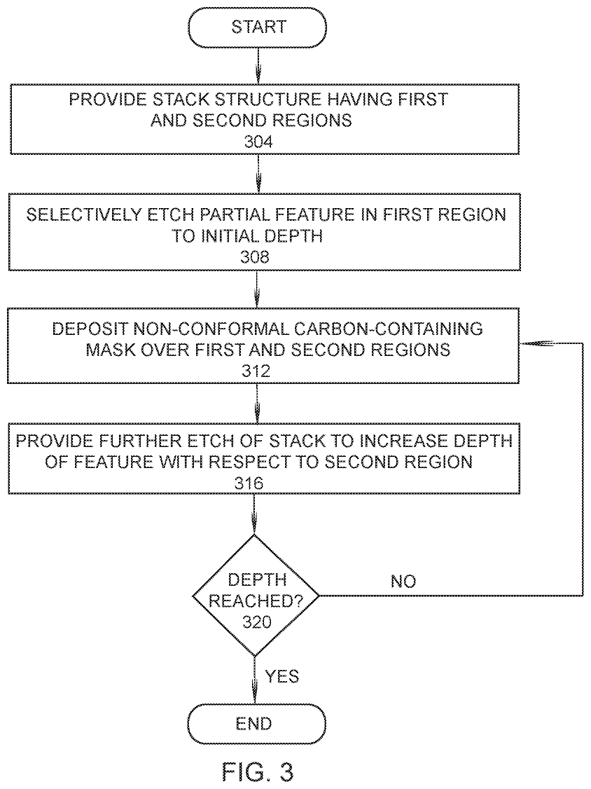

In another embodiment, the depth after further etch step 116 is not sufficient (e.g., d₂≠d_{final}). In such case, deposition step 112 and further etch step 116 may be iteratively cycled until depth d_{final} is achieved. As illustrated in FIG. 3, a stack structure 200 with first and second regions is provided (step 304). After the stack structure 200 is provided, a selective, partial etch is performed (step 308) that partially etches feature 220 in one or more of the first regions 204 that are not covered by the photolithographic mask 212. A deposition step (step 312) is performed in-situ in the same chamber used to process the partial etch step 308 to form a fluorine-free, carbon-containing, non-conformal mask 224 over the non-masked regions of the stack structure 200. Next, a further etch of the stack structure 200 is performed at step 316 in-situ in the same chamber as steps 308 and 312 to add additional depth to the trench or feature 220 with respect to the layer surface 216. At step 320, a determination is made as to whether the desired depth is reached. If not (e.g., d₂≠d_{final}), steps 312 and 316 are repeated until the final depth is achieved (e.g., d₂=d_{final}). The determination at step 320 may be made via sensor, or automatically if the depth of the further etch at step 316 is repeatable and/or predictable.

For purposes of this description and the process steps in shown in FIG. 1, FIG. 2A through FIG. 2D, and FIG. 3, in-situ is defined to mean that all the processes (e.g., partial etch, mask deposition, further etch) are done in the same chamber on the same substrate support and under the same gas feed.

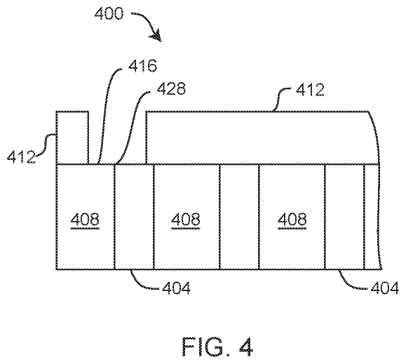

FIG. 4 is a schematic cross-sectional view of part of a stack structure 400 having alternating first regions 404 and second regions 408, wherein the mask 412 exposes a much smaller portion of surface 416. In this embodiment, only one corner 428 of one second region 408 is exposed to eventually form a contact within first region 404 and corresponding gate within second region 408.

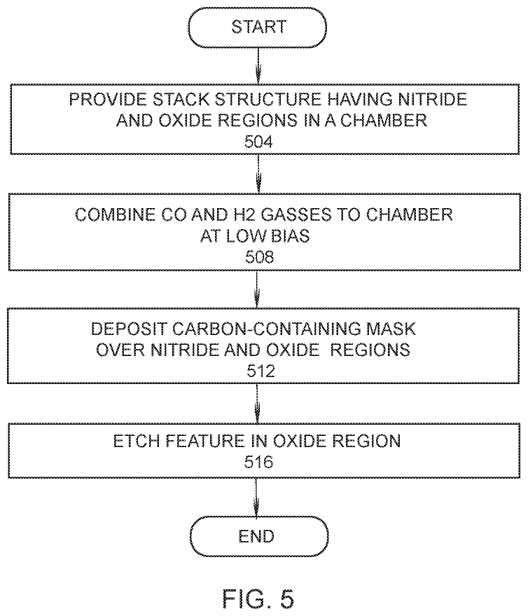

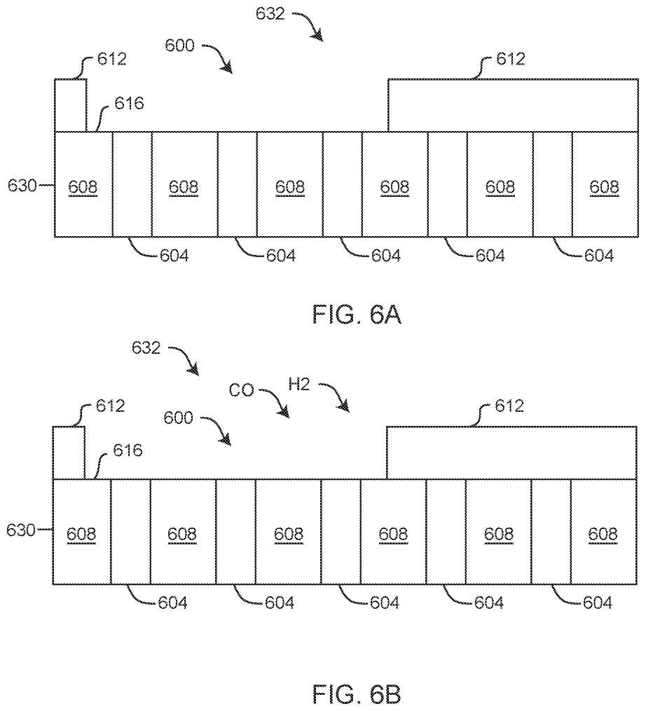

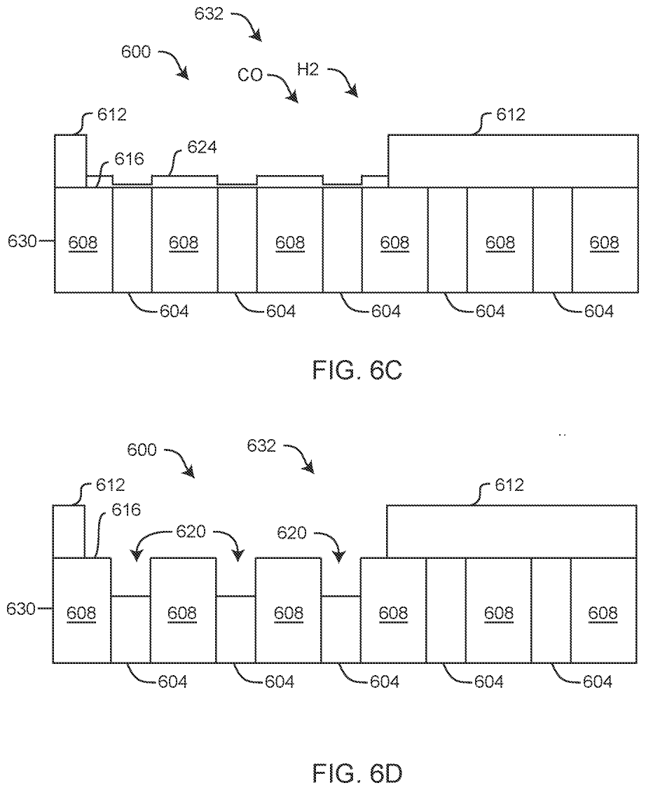

FIG. 5 is a high-level flow diagram of another embodiment employed for in-situ passivation of a nitride region with respect to an oxide region that selectively deposits a carbon-based film or mask on the nitride region at a much higher rate than on the oxide. A stack structure with a nitride region and oxide region is provided (step 504). FIG. 6A is a schematic cross-sectional view of part of a stack structure 600 with alternating oxide regions 604 and nitride regions 608 within layer 630 disposed within a semiconductor processing or reactor chamber 632 (e.g., capacitively coupled small gap etch reactor chamber). In one embodiment, layer 630 comprises a layer that eventually forms contacts within oxide regions 604 and gates within second regions 608. In this example, the oxide region 604 comprises a stable oxide such as silicon oxide (SiO) or silicon dioxide (SiO₂). In one embodiment, the nitride region 608 material may include, for example, silicon nitride (SiN), silicon oxynitride (SiON), silicon oxycarbonitride (SiOCN), silicon oxynitride (SiON), silicon carbonitride (SiCN), or the like material.

A mask 612 is formed over surface 616 of the layer 630. In one embodiment, the mask 212 comprises a photolithographic mask of patterned photoresist. As shown in FIG. 6A through FIG. 6D, the mask 612 may be configured to expose a number of alternating oxide regions 604 and nitride regions 608, or just one region or corner of a region as shown in FIG. 4.

The selective deposition (PECVD) processes may be implemented as part of an etch that is targeted to remove SiO₂ for small-CD SAC etching. In this embodiment, the selective deposition process utilizes the distinctive material properties between the nitride and oxide regions, along with the environment within the etch chamber, to generate a non-conformal carbon-based mask.

After the stack structure 600 is provided, CO gas (and optionally combined with H₂) is added (step 508) in the reactor chamber 632, and bias is kept fairly low (e.g., 15 watts (W), 2 megahertz (MHz) power). In one embodiment, “low-bias” means a bias less than 60 W, and more specifically ranging between 60 W and 10 W at a frequency between 2 (megahertz) MHz and 400 (kilohertz) kHz. FIG. 6B is a schematic cross-sectional view of the stack structure 600 with CO and H₂ gasses being added to the reactor chamber 632.

With the CO gas present in the reactor chamber 632, a carbon-based, non-conformal mask 624 is selectively deposited (step 512) on the non-masked region such that the mask on the nitride region 608 is deposited at a much higher rate than on the oxide region 604, creating a thicker layer on the nitride region 608 than the oxide region 604. FIG. 6C is a schematic cross-sectional view of the stack structure 600 after deposition of the mask 624. This passivation via the sacrificial thicker layer of mask 624 on the nitride region 608 reduces the subsequent etching of the nitride region 608, without hindering the etch of the target oxide region 604.

With the carbon-based, non-conformal mask 624 in place, an etch (step 516) is performed in-situ on the stack structure 600, removing the mask 624 and etching the oxide regions 604 to form a feature 620 (e.g., trench) in the oxide regions 604. FIG. 6D is a schematic cross-sectional view of the stack structure 600 after etching step 516 has been performed.

In one embodiment, the deposited mask 624 may be tuned to have the following desired capabilities: (1) minimal loading at the cap level for a range of features and (2) the deposited mask 624 having optimal resistance to the etch process to protect the nitride region 608.

While the in-situ selective deposition processes detailed above are particularly suited to SAC, the capabilities described for the in-situ selective passivation may have value for other applications where high etch selectivity is desired. For example, in-situ selective deposition processes may be used for any application with a SiN mask over a SiO₂ target etch film. Also, the in-situ selective deposition processes may be implemented as an area-selective deposition of a carbon-based film on SiN vs SiO₂, and possibly selective to other materials. The in-situ selective deposition processes may also be used as a protective sacrificial film to enable area-selective deposition on SiO₂ but not SiN.

FIG. 7 is a schematic view of an etch reactor that may be used in an embodiment. In one or more embodiments, an etch chamber 700 comprises a gas distribution plate 706, in the form of a showerhead, providing a gas inlet and an electrostatic chuck (ESC) 734, within a plasma processing chamber 749, enclosed by a chamber wall 752. Within the plasma processing chamber 749, a wafer or stack structure 200 is positioned over the ESC 734, with an edge ring 736 surrounding the stack structure. The ESC 734 may provide a bias from the ESC source 748. An etch gas source 710 is connected to the plasma processing chamber 749 through the gas distribution plate 706. The etch gas source 710 may be a modification gas source and an activation gas source. An ESC temperature controller 750 is connected to a chiller 714. In this embodiment, the chiller 714 provides a coolant to channels 712 in or near the ESC 734. A radio frequency (RF) source 730 provides RF power to a lower electrode and/or an upper electrode. In this embodiment, the lower electrode is the ESC 734 and the upper electrode is the gas distribution plate 706. In an exemplary embodiment, 400 kHz, 60 MHz, and optionally 2 MHz, 27 MHz power sources make up the RF source 730 and the ESC source 748. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments.

A controller 735 is controllably connected to the RF source 730, the ESC source 748, an exhaust pump 720, and the etch gas source 710. An example of such an etch chamber is the Exelan Flex™ or Flex GL® etch system manufactured by Lam Research Corporation of

Fremont, Calif. In this embodiment, the etch chamber 700 provides capacitively coupled plasma energy. The process chamber can be a CCP (capacitively coupled plasma) reactor or an ICP (inductively coupled plasma) reactor. Other embodiments may use other types of plasma processing chambers such as dielectric and conductive etch chambers or deposition chambers.

A high flow liner 760 is provided within the plasma processing chamber 749, and confines gas from the gas source and has slots 702 to maintain a controlled flow of gas to pass from the gas source 710 to the exhaust pump 720.

To provide an example of a controller 735 in an embodiment, FIG. 8 is a high level block diagram showing a computer system 800 that is suitable for implementing a controller 735 used in embodiments. The computer system may have many physical forms ranging from an integrated circuit, a printed circuit board, and a small handheld device, up to a huge supercomputer. The computer system 800 includes one or more processors 802, and further can include an electronic display device 804 (for displaying graphics, text, and other data), a main memory 806 (e.g., random access memory (RAM)), storage device 808 (e.g., hard disk drive), removable storage device 810 (e.g., optical disk drive), user interface devices 812 (e.g., keyboards, touch screens, keypads, mice or other pointing devices, etc.), and a communication interface 814 (e.g., wireless network interface). In one embodiment, main memory 806 comprises a non-transitory memory for storing instructions executable on one or more processors 802. The communication interface 814 allows software and data to be transferred between the computer system 800 and external devices via a link. The system may also include a communications infrastructure 816 (e.g., a communications bus, cross-over bar, or network) connected to the aforementioned devices/modules.

Information transferred via communications interface 814 may be in the form of signals such as electronic, electromagnetic, optical, or other signals capable of being received by communications interface 814, via a communication link that carries signals and may be implemented using wire or cable, fiber optics, a phone line, a cellular phone link, a radio frequency link, and/or other communication channels. With such a communications interface, it is contemplated that the one or more processors 802 might receive information from a network or might output information to the network in the course of performing the above-described method steps. Furthermore, method embodiments may execute solely upon the processors or may execute over a network, such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as one produced by a compiler, and files containing higher level code that are executed by a computer using an interpreter.

Computer readable media may also be computer code transmitted by a computer data signal embodied in a carrier wave and representing a sequence of instructions that are executable by a processor.

While this disclosure has been described in terms of several exemplary embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for selectively etching at least one feature in a first region with respect to a second region of a stack, comprising:
a) selectively etching the first region with respect to the second region to form at least one partial feature in the first region, the at least one partial feature having a depth with respect to a surface of the second region;
b) depositing in-situ a fluorine-free, non-conformal, carbon-containing mask over the first region and the second region, wherein the carbon-containing mask is selectively deposited on the second region at a second thickness with respect to the first region at a first thickness, the second thickness being greater than the first thickness; and
c) further etching in-situ the first region to etch the at least one partial feature and wherein the carbon-containing mask acts as an etch mask for the second region.

2. The method, as recited in claim 1, wherein the first region comprises a silicon oxide region and the second region comprises a lower oxygen region.

3. The method, as recited in claim 2, wherein the second region comprises a silicon nitride region.

4. The method, as recited in claim 1, wherein selectively etching the first region comprises etching at least one partial feature to a depth of at least 20 nm.

5. The method, as recited in claim 1, wherein the carbon-containing mask comprises a hydrocarbon.

6. The method, as recited in claim 5, wherein the carbon-containing mask is deposited via plasma-enhanced chemical vapor deposition (PECVD).

7. The method, as recited in claim 6, wherein the further etching is an atomic layer etch.

8. The method, as recited in claim 7, further comprising repeating steps b and c.

9. The method, as recited in claim 1, wherein the carbon-containing mask is deposited at a temperature of between 20° C. and 250° C.

10. The method, as recited in claim 1, wherein the further etching is an atomic layer etch.

11. The method, as recited in claim 1, further comprising repeating steps b and c.

12. The method, as recited in claim 1, further comprising ashing the carbon-containing mask.

13. The method, as recited in claim 1, wherein the at least one partial feature in the first region forms a recessed region of the stack and remaining portions of the stack form a non-recessed region of the stack and wherein depositing in-situ a fluorine-free, non-conformal, carbon-containing mask over the first region and the second region comprises selectively depositing on the non-recessed region with respect to the recessed region based on geometry.

14. An apparatus for selectively etching at least one feature in a first region with respect to a second region of a stack, comprising:
(a) a processor; and
(b) a non-transitory memory storing instructions executable by the processor;
(c) wherein said instructions, when executed by the processor, perform steps comprising:
i) selectively etching the first region with respect to the second region to form at least one partial feature in the first region, the at least one partial feature having a depth with respect to a surface of the second region;
ii) depositing in-situ a fluorine-free, non-conformal, carbon-containing mask over the first region and the second region, wherein the carbon-containing mask is selectively deposited on the second region at a second thickness with respect to the first region at a first thickness, the second thickness being greater than the first thickness; and
iii) further etching in-situ the first region to etch the at least one partial feature and wherein the carbon-containing mask acts as an etch mask for the second region.

15. The apparatus, as recited in claim 14, wherein the first region comprises a silicon oxide region and the second region comprises a lower oxygen region.

16. The apparatus, as recited in claim 15, wherein the second region comprises a silicon nitride region.

17. The apparatus, as recited in claim 14, wherein selectively etching the first region comprises etching at least one partial feature to a depth of at least 20 nm.

18. The apparatus, as recited in claim 14, wherein the carbon-containing mask comprises a hydrocarbon.

19. The apparatus, as recited in claim 18, wherein the carbon-containing mask is deposited via plasma-enhanced chemical vapor deposition (PECVD).

20. The apparatus, as recited in claim 19, wherein the further etching is an atomic layer etch.

21. A method for selectively etching at least one feature in an oxide region with respect to a nitride region of a stack, comprising:
providing a stack structure with a nitride region and oxide region in a reactor chamber;
adding CO gas in the reactor chamber at a bias of less than 60 W;
selectively depositing a carbon-based mask such that the mask on the nitride region is deposited at a higher rate than on the oxide region, creating a thicker layer on the nitride region than the oxide region; and
performing an etch in-situ on the stack, thereby etching the oxide region to form a feature in the oxide region.

22. The method, as recited in claim 21, wherein the oxide region comprises SiO₂.

23. The method, as recited in claim 21, wherein the nitride region comprises SiN.

24. The method, as recited in claim 21, wherein H₂ gas is combined with the CO gas in the reactor chamber.
